(19) United States
(12) Patent Application Publication
(10) Pub. No.: US 2021/0050548 A1
(43) Pub. Date: Feb. 18, 2021

(54) DISPLAY PANEL

(71) Applicant: SHENZHEN CHINA STAR OPTOELECTRONICS SEMICONDUCTOR DISPLAY TECHNOLOGY CO., LTD, Shenzhen,Guangdong (CN)

(72) Inventor: Weijing ZENG, Shenzhen, Guangdong (CN)

(21) Appl. No.: 16/620,873

(22) PCT Filed: Nov. 11, 2019
(86) PCT No.: PCT/CN2019/117183

§ 371 Date: Dec. 10, 2019

(30) Foreign Application Priority Data
Aug. 15, 2019 (CN) 201910755785.6

(51) Int. Cl. H01L 51/52

(52) U.S. Cl. CPC H01L 51/5218; H01L 2251/308; H01L 2251/306

(57) ABSTRACT

A display panel is provided. The display panel includes a substrate, a thin film transistor layer, and a light emitting structure. The light emitting structure includes: an anode disposed on the thin film transistor layer and electrically connected to the thin film transistor layer; a light emitting material layer disposed on the anode; and a cathode covering the light emitting material layer. The light emitting structure further includes an anode reflective layer disposed below the anode and electrically insulated from the anode by a reflective isolation layer.

### FIELD OF INVENTION

The present disclosure relates to the field of electronic display technologies, and more particularly to a display panel.

### BACKGROUND OF INVENTION

Organic light emitting diode (OLED) display panels are widely used in mobile phone screens, displays, and full-color televisions (TVs) because of their self-illumination, high brightness, wide viewing angles, high contrast, flexibility, and low power consumption.

Anode of a top emitting OLED structure generally adopts a laminated structure composed of indium tin oxide (ITO) and silver (Ag). In order to match the anode to energy levels of an organic light emitting material layer, material in which the anode is in direct contact with an organic material is ITO. In addition, since the anode needs to be used as a reflective electrode, the anode also needs to be provided with metal having high reflectivity for reflection, such as Ag.

However, Ag is easily oxidized in air to form silver oxide bumps, which causes the anode and cathode of an OLED device to be short-circuited, so that pixel dots cannot emit light, which affects performance of display image.

### SUMMARY OF INVENTION

An embodiment of the present invention provides a display panel, which can solve display anomalies caused by anodization in the prior art.

In order to solve the above issues, an embodiment of the present application provides a display panel. The display panel comprises a substrate, a thin film transistor layer, and a light emitting structure. The light emitting structure comprises: an anode disposed on the thin film transistor layer and electrically connected to the thin film transistor layer; a light emitting material layer disposed on the anode; and a cathode covering the light emitting material layer. The light emitting structure further comprises an anode reflective layer disposed below the anode and electrically insulated from the anode by a reflective isolation layer.

In an embodiment of the present application, material of the anode comprises a combination of one or more of indium tin oxide, aluminum-doped zinc oxide, and fluorine-doped tin oxide.

In an embodiment of the present application, material of the anode reflective layer comprises a combination of one or more of silver, copper, aluminum, gold, and iron.

In an embodiment of the present application, the material of the anode reflective layer is silver.

In an embodiment of the present application, a minimum distance between the anode reflective layer and the light emitting material layer is less than or equal to 5 times a thickness of the anode reflective layer.

In an embodiment of the present application, a surface of the anode reflective layer is a smooth mirror structure.

In an embodiment of the present application, the light emitting structure further comprises a pixel defining layer covering the thin film transistor layer and having an opening exposing the anode, and the light emitting material layer is disposed in the opening.

In an embodiment of the present application, the reflective isolation layer is disposed between the pixel defining layer and the thin film transistor layer; wherein the anode reflective layer is disposed corresponding to the light emitting material layer, and an area of the anode reflective layer is greater than an area of the light emitting material layer.

In an embodiment of the present application, a projection of the anode reflective layer on a light emitting surface of the display panel completely covers a projection of the light emitting material layer on the light emitting surface of the display panel.

In an embodiment of the present application, a minimum distance between the anode reflective layer and the anode is greater than or equal to 2.5 times a thickness of the anode reflective layer.

Beneficial effects of the present application are that: the anode of the display panel of an embodiment of the present application is indium tin oxide for matching work function of a light emitting material in the light emitting material layer to improve light emitting efficiency of the display panel. In addition, in order to improve utilization of light, an embodiment of the present application provides an anode reflective layer under the anode of the light emitting structure. Compared with an anode structure in which indium tin oxide and a reflective material are combined in the prior art, an embodiment of the present application effectively avoids pixel point failure phenomenon caused by oxidation of a reflective material.

### DESCRIPTION OF DRAWINGS

FIG. 1 is a schematic structural view of a display panel in the prior art.

FIG. 2 is a schematic structural view of a display panel according to an embodiment of the present application.

### DETAILED DESCRIPTION OF PREFERRED EMBODIMENTS

The following description of the various embodiments is provided to illustrate the specific embodiments of the present invention. The directional terms mentioned in the present application, such as up, down, front, back, left, right, inside, outside, side, etc., are only directions referring to the additional drawings. Therefore, the directional terminology used is for the purpose of illustration and understanding and is not intended to be limiting. In the figures, structurally similar elements are denoted by the same reference numerals.

First, the prior art will be briefly described.

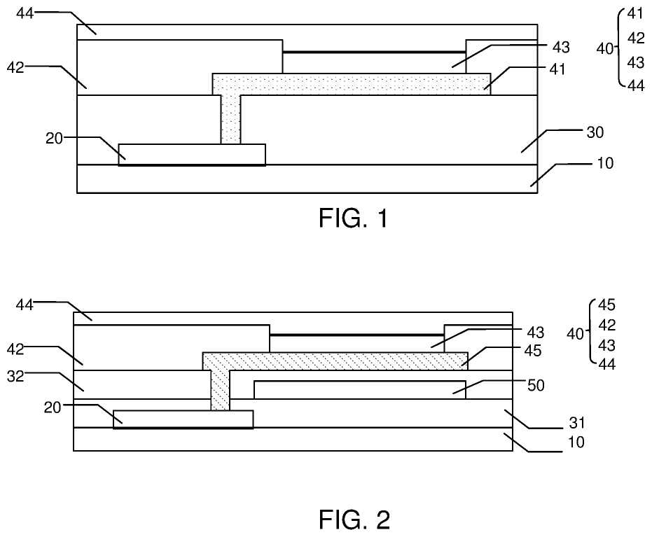

Referring to FIG. 1, FIG. 1 is a schematic structural view of a display panel in the prior art. The display panel is a top emitting display panel, that is, a light emitting surface of the display panel is a surface of a cathode of a light emitting structure that is away from an anode.

Referring to FIG. 1, the display panel of the prior art includes a substrate 10, a thin film transistor 20, a planarization layer 30, and a light emitting structure 40. The light emitting structure 40 is disposed above the planarization layer and includes an anode 41, a pixel defining layer 42, a light emitting material layer 43, and a cathode 44. The anode 41 is disposed on the planarization layer 30 and electrically connected to the thin film transistor 20 through a through hole. The pixel defining layer 42 covers the planarization layer 30 and has an opening exposing the anode 41. The light emitting material layer 43 is disposed in the opening, and the cathode 44 covers the light emitting material layer 43.

Since a surface of the cathode away from the anode is a light emitting surface, the cathode is a transparent electrode. Further, in order to improve light utilization, the anode is a reflective electrode. In the prior art, in order to match energy levels of the anode and an organic light emitting material layer, the material in which the anode is in direct contact with an organic material is ITO. In addition, since the anode needs to be used as a reflective electrode, the anode also needs to be provided with metal having high reflectivity for reflection, and the metal generally used as a reflective material is Ag. However, Ag is highly oxidized in the air to form silver oxide bumps. The silver bumps cause the anode and cathode of an OLED device to be short-circuited, so that pixel dots cannot emit light, which affects display performance.

To solve the above issues, an embodiment of the present application provides a display panel. Referring to FIG. 2, the display panel includes a substrate 10, a thin film transistor layer 20, and a light emitting structure 40. The light emitting structure 40 includes an anode 45, a pixel defining layer 42, a light emitting material layer 43, a cathode 44, and an anode reflective layer 50.

The anode 45 is electrically connected to the thin film transistor 20 through a via hole. The pixel defining layer 42 covers the planarization layer 30 and has an opening exposing the anode 41. The light emitting material layer 43 is disposed in the opening, and the cathode 44 covers the light emitting material layer 43.

In an embodiment of the present application, the anode 45 and the cathode 44 are both light transmissive electrodes. Materials of the anode 45 and the cathode 44 comprises a transparent conductive material, such as a combination of one or more of indium tin oxide, aluminum-doped zinc oxide, and fluorine-doped tin oxide. In one embodiment of the present application, the anode 45 is formed using a transparent material to strip a reflective metal out of the anode 45. The transparent conductive material not only matches work function of the light emitting material more closely, but also avoids the metal being oxidized to generate bumps, causing the anode 45 and the cathode 44 to be short-circuited, and thus improving performance of the display panel.

Since the reflective metal is peeled off from the anode 45, an anode reflective layer 50 is disposed in the light emitting structure 40 in order not to reduce the light utilization of the light emitting structure 40. In an embodiment of the present application, material of the anode reflective layer 50 comprises metal having high reflectivity, such as a combination of one or more of silver, copper, aluminum, gold, and iron. In this embodiment, the material of the anode reflective layer 50 is silver. Preferably, in order to enhance ability of the anode reflective layer to reflect light, a surface of the anode reflective layer is a smooth mirror structure. The mirror structure minimizes light loss caused by diffuse reflection and further improves the light utilization of the light emitting structure. In practice, since the surface of the metal layer formed by electroplating is a mirror structure, the anode reflective layer 50 is preferably formed by electroplating.

Referring to FIG. 2, the anode reflective layer 50 is disposed below the anode 45 and is electrically insulated from the anode 45 by a reflective isolation layer 32. The reflective isolation layer 32 is disposed between the planarization layer 31 and the pixel defining layer 42. Material of the reflective isolation layer 32 comprises an insulating material such as silicon nitride, silicon oxide, or the like. The reflective isolation layer 32 covers the anode reflective layer 50 to achieve electrical insulation between the anode 45 and the anode reflective layer 59.

In order to prevent conductive bumps generated after the anode reflective layer 50 is oxidized from being electrically connected to the anode 45, a minimum distance between the anode reflective layer 50 and the anode 45 is greater than or equal to 2.5 times a thickness of the anode reflective layer 50. In an embodiment of the present application, the minimum distance between the anode reflective layer 50 and the anode 45 refers to a vertical distance between a surface of the anode reflective layer 50 facing the anode 45 and a surface of the anode 45 facing the anode reflective layer 50. Since a volume of silver oxide produced by oxidation of metallic silver is 2.47 times a volume of an original metallic silver. In practice, in order to avoid electrical connection between the conductive bumps generated by the oxidation of the anode reflective layer 50 and the anode 45, it is necessary to set the minimum distance between the anode reflective layer 50 and the anode 45 to be greater than or equal to 2.5 times the thickness of the anode reflective layer 50. That is, in the embodiment of the present application, the thickness of the reflective isolation layer 32 disposed directly above the anode reflective layer 50 is greater than or equal to 2.5 times the thickness of the anode reflective layer 50.

In addition, since the thickness of the anode reflective layer 50 is increased, a thickness of the display panel is inevitably increased, the minimum distance between the anode reflective layer 50 and the anode 45 is less than or equal to 5 times the thickness of the anode reflective layer 50.

In an embodiment of the present application, the anode reflective layer 50 is disposed corresponding to the light emitting material layer 43. Specifically, the anode reflective layer 50 is disposed directly under the light emitting material layer 43. In addition, in order to ensure that the anode reflective layer can reflect all the light emitted by the light emitting structure 40 back to a light exit surface, an area of the anode reflective layer 50 is larger than an area of the light emitting material layer 43. In this embodiment, a projection of the anode reflective layer 50 on a light emitting surface of the display panel completely covers a projection of the light emitting material layer 43 on the light emitting surface of the display panel.

As can be seen from the above embodiments, the embodiment of the present application peels off the reflective metal and the transparent conductive material in the reflective anode of the prior art and separately sets them. Thereby, the anode and cathode short circuits due to the oxidation of the reflective metal are avoided while ensuring the reflective effect of the anode.

The anode of the display panel of an embodiment of the present application is indium tin oxide for matching work function of a light emitting material in the light emitting material layer to improve light emitting efficiency of the display panel. In addition, in order to improve utilization of light, an embodiment of the present application provides an anode reflective layer under the anode of the light emitting structure. Compared with an anode structure in which indium tin oxide and a reflective material are combined in the prior art, an embodiment of the present application effectively avoids pixel point failure phenomenon caused by oxidation of a reflective material.

In summary, although the present application has been disclosed above in the preferred embodiments, the above preferred embodiments are not intended to limit the present application. Various modifications and refinements can be made by those skilled in the art without departing from the spirit and scope of the present application. The protection scope of the present application is therefore defined by the scope of the claims.

What is claimed is:

1. A display panel, wherein the display panel comprises a substrate, a thin film transistor layer, and a light emitting structure; the light emitting structure comprises:
an anode disposed on the thin film transistor layer and electrically connected to the thin film transistor layer;
a light emitting material layer disposed on the anode; and
a cathode covering the light emitting material layer;
wherein the light emitting structure further comprises an anode reflective layer disposed below the anode and electrically insulated from the anode by a reflective isolation layer.

2. The display panel according to claim 1, wherein material of the anode comprises a combination of one or more of indium tin oxide, aluminum-doped zinc oxide, and fluorine-doped tin oxide.

3. The display panel according to claim 2, wherein material of the anode reflective layer comprises a combination of one or more of silver, copper, aluminum, gold, and iron.

4. The display panel according to claim 3, wherein the material of the anode reflective layer is silver.

5. The display panel according to claim 4, wherein a minimum distance between the anode reflective layer and the light emitting material layer is less than or equal to 5 times a thickness of the anode reflective layer.

6. The display panel according to claim 3, wherein a surface of the anode reflective layer is a smooth mirror structure.

7. The display panel according to claim 1, wherein the light emitting structure further comprises a pixel defining layer covering the thin film transistor layer and having an opening exposing the anode, and the light emitting material layer is disposed in the opening.

8. The display panel according to claim 7, wherein the reflective isolation layer is disposed between the pixel defining layer and the thin film transistor layer; wherein the anode reflective layer is disposed corresponding to the light emitting material layer, and an area of the anode reflective layer is greater than an area of the light emitting material layer.

9. The display panel according to claim 8, wherein a projection of the anode reflective layer on a light emitting surface of the display panel completely covers a projection of the light emitting material layer on the light emitting surface of the display panel.

10. The display panel according to claim 1, wherein a minimum distance between the anode reflective layer and the anode is greater than or equal to 2.5 times a thickness of the anode reflective layer.
